(19) United States
(12) Patent Application Publication
(10) Pub. No.: US 2019/0058084 A1
(43) Pub. Date: Feb. 21, 2019

(54) Laser Diodes, LEDs, and Silicon Integrated sensors on Patterned Substrates

(71) Applicant: Jie Piao, Dix Hills, NY (US)

(72) Inventor: Jie Piao, Dix Hills, NY (US)

(21) Appl. No.: 15/680,345

(22) Filed: Aug. 18, 2017

(51) Int. Cl. H01L 33/00; H01S 5/02; H01L 33/02

(52) U.S. Cl. CPC H01L 33/0075; H01S 5/0206; H01S 2304/00; H01L 33/02; H01L 33/0054

(57) ABSTRACT

Patterned substrates and optoelectronic devices (UV laser diode, UV LED, and sensors grown on silicon substrate) formed on these patterned substrates are described. The method of making patterned substrates are described. Examples of making laser diodes on these patterned substrates described in detail. The PSs can be fabricated by either combination of e-beam lithography and wet-chemical etching or combination of e-beam lithography and dry etching or through Nanoimprint transfer of master mold patterns to various wafers followed by etching.

### BACKGROUND OF THE INVENTION

The present invention is directed to patterned substrate and it's fabrication that will results in an improved optoelectronic devices including laser diode (LDs), light-emitting diodes (LEDs), and silicon integrated sensors (sensors on silicon substrate). More specifically, the present invention is related to an ultraviolet (UV) laser diodes (UV LDs), light emitting diodes (LEDs), and sensors on silicon and silicon dioxide on silicon temperate which can be manufactured without a low temperature buffer layer, with greatly reduced dislocation density thereby providing improved efficiency, and performance.

Group III nitride compound semiconductors such as, for instance, gallium nitride (GaN), aluminum nitride (AlN), and indium nitride (InN) (hereinafter also referred to as a “Group III-nitride semiconductor” or “III-nitrides”) have been gaining attention as a material for semiconductor devices that emit green, blue or ultraviolet light.

UV LDs, LEDs, and sensors are highly desirable for a number of applications and proposed applications. They are expected to find great utility in such diverse areas as bio chemical sensors, air and Water purification, food processing and packaging, displays, lighting and for high-density optical disk devices, and various forms of medical applications such as dentistry, dermatology and optometry.

These LDs, LEDs, and sensors are difficult to manufacture for a few reasons. For example, defects arise from lattice and thermal mismatch between the groups III-Nitride based active device layers and a substrate such as silicon, sapphire, Gallium Nitride, or silicon carbide on which they are constructed. In addition, impurities and tilt boundaries result in the formation of crystalline defects. These defects have been shown to reduce the efficiency and lifetime of LEDs and LDs fabricated from these materials. These defects have been observed for III-Nitride films grown on the above mentioned substrates with typical dislocation densities ranging from 10⁸ cm² to 10¹⁰ cm ⁻² for films grown via metal-organic chemical vapor deposition (MOCVD), molecular beam epitaxy (MBE), hydride vapor phase epitaxy (HVPE) and several other less common growth techniques. Therefore reducing the dislocation density has become one of focused research.

Many approaches were studied to reduce dislocation density. One of which is use of epitaxial lateral overgrowth (ELOG), and variations of this approach including lateral growth (PENDEO) epitaxy, and facet controlled epitaxial lateral overgrowth (FACELO), which are all well-known technique in the prior art. With these method, the dislocation density can be reduced to about 10⁵ cm⁻² to 10⁶ cm⁻². These method, however, has been shown to be ineffective for the growth of aluminum-containing III-Nitride based semiconductors because of the tendency for the aluminum to stick to the masked material and disrupt the lateral overgrowth.

There are many other approaches to reduce defect densities.

In spite of the many developments and advancements there remains significant limitation for developing high power, LDs, reliable UVLEDs, and sensors integrated on silicon substrate. Hence there is an ongoing desire for LDs, LEDs, and silicon integrated sensors and method for forming LDs, LEDs, and silicon integrated sensors with a low defect density.

### BRIEF SUMMARY OF THE INVENTION

This invention discloses three patterned substrates which enables greatly reduced dislocation density on films grown on them, and the designs and structures of laser diodes and methods of fabricating such devices on these patterned substrates. The patterned substrates will be made with (formed on) various wafers including Si, GaN-on-sapphire, or GaN, sapphire wafers.

This invention presents a method to grow and fabricate high crystalline quality semiconductor optoelectronic device structures and devices on nano/micro patterned substrates. The optoelectronic device including LDs, LEDs, and silicon integrated sensors including SiGeSn on silicon and silicon oxides (SiOₓ, 1≤x) on silicon temperate. This invention enables mass fabrication of high performance laser diodes (and other optoelectronic and photonic devices) on patterned substrates.

### BRIEF DESCRIPTION OF THE DRAWINGS

FIG. 1 describes the substrate 1;

FIG. 2 depicts the schematic of a V-groove patterned substrate 2;

FIG. 2a depicts the cross sectional view of the V-groove patterned substrate 2;

FIG. 2b depicts the cross sectional view of the V-groove patterned substrate 2 in case of the trench width is equal to 0;

FIG. 3 depicts the schematic of the first layer of laser structure (bottom cladding layer 3) on V-groove patterned substrate;

FIG. 4 depicts the schematic of the second layer of laser structure (bottom waveguide layer 4) on V-groove patterned substrate;

FIG. 5 depicts the schematic of the laser structure after growing the active region 5;

FIG. 6 depicts the schematic of the laser structure after growing the top waveguide layer 6;

FIG. 7 depicts the schematic of the laser structure after growing the top cladding layer 7;

FIG. 8 depicts the schematic of the laser structure after growing contact layer 8;

FIG. 9 depicts the schematic of the laser structure after depositing top metal contact 9;

FIG. 10 depicts the schematic of the laser structure after depositing bottom metal contact 10;

FIG. 11 depicts the laser chip with single laser diode on V-groove patterned substrate after forming two mirrored facets with cleaving;

FIG. 12 depicts the cross sectional view of single laser diode on V-groove patterned substrate;

FIG. 13 depicts the schematic of a trapezoidal-groove patterned substrate 11;

FIG. 13a depicts the cross sectional view of the a trapezoidal-groove patterned substrate 11;

FIG. 14 depicts the schematic of the first layer of laser structure (bottom cladding layer 12) on trapezoidal-groove patterned substrate;

FIG. 15 depicts the schematic of the second layer of laser structure (bottom waveguide layer 13) on trapezoidal-groove patterned substrate;

FIG. 16 depicts the schematic of the laser structure after growing the active region 14;

FIG. 17 depicts the schematic of the laser structure after growing the top waveguide layer 15;

FIG. 18 depicts the schematic of the laser structure after growing the top cladding layer 16;

FIG. 19 depicts the schematic of the laser structure after growing contact layer 17;

FIG. 20 depicts the schematic of the laser structure after depositing top metal contact 18;

FIG. 21 depicts the schematic of the laser structure after depositing bottom metal contact 19;

FIG. 22 depicts the laser chip with single laser diode on trapezoidal-groove patterned substrate after forming two mirrored-facets with cleaving;

FIG. 23 depicts the cross sectional view of laser diode on trapezoidal-groove patterned substrate;

FIG. 24 depicts the schematic of a rectangular cuboid-groove patterned substrate 20;

FIG. 24a depicts the cross sectional view of the rectangular cuboid-groove patterned substrate 20;

FIG. 25 depicts the cross section view of a single laser diode on cuboid-groove patterned substrate;

FIG. 26 depicts the schematic of the laser structure after depositing top and bottom metal contacts;

FIG. 27 depicts single laser diode on cuboid-groove patterned substrate after forming two mirrored facets with cleaving;

FIG. 28 presents the fabrication procedure of patterned substrate by nanoimprint lithography;

### DETAILED DESCRIPTION OF THE INVENTION

This invention is fallen into the field of optoelectronics, particularly, is the design, epitaxial growth, fabrication, and characterization of Laser Diodes (LDs) operating in the ultraviolet (UV) to infrared (IR) spectral regime on patterned substrates (PSs) made with (formed on) low cost, large size Si, or GaN on sapphire, GaN, and other wafers. We disclose three types of PSs, which can be a universal substrates, allowing any materials (III-Vs, II-VIs, etc.) grown on top of it with low defect/and or dislocation density. Molecular beam epitaxy (MBE), metal-organic chemical vapor deposition (MOCVD), chemical vapor deposition (CVD) or any other epitaxial growth method can be employed to grow high quality nearly/perfectly dislocation free device structures on these three PSs. Therefore, these PSs enable mass fabrication of high performance LDs operating from UV to IR spectral range. These PSs also enable mass fabrication of other optoelectronic and photonic devices based on III-Vs, II-VIs and other materials including III-Nitride materials.

Decades of extensive efforts to develop III-Vs or II-VIs based LDs monolithically grown on planer Silicon substrates has been unsuccessful due to large lattice mismatch between LD materials and silicon substrate. Three PSs disclosed in this invention enable monotheistic integration of these LDs with silicon based devices/circuits.

As the III-nitride based LDs an example, up to date, no low cost commercial UV and green LDs available due to lack of low cost/and or lattice matched substrates. Three types of PSs enable high quality GaN, AlGaN, and InGaN films on these PSs formed on silicon, GaN-on-sapphire, or GaN substrates, thereby enables commercial UV and green LDs on these PSs.

Three types of PSs are V-groove PS 2, trapezoidal-groove PS 13, and rectangular/square cuboid PS 20.

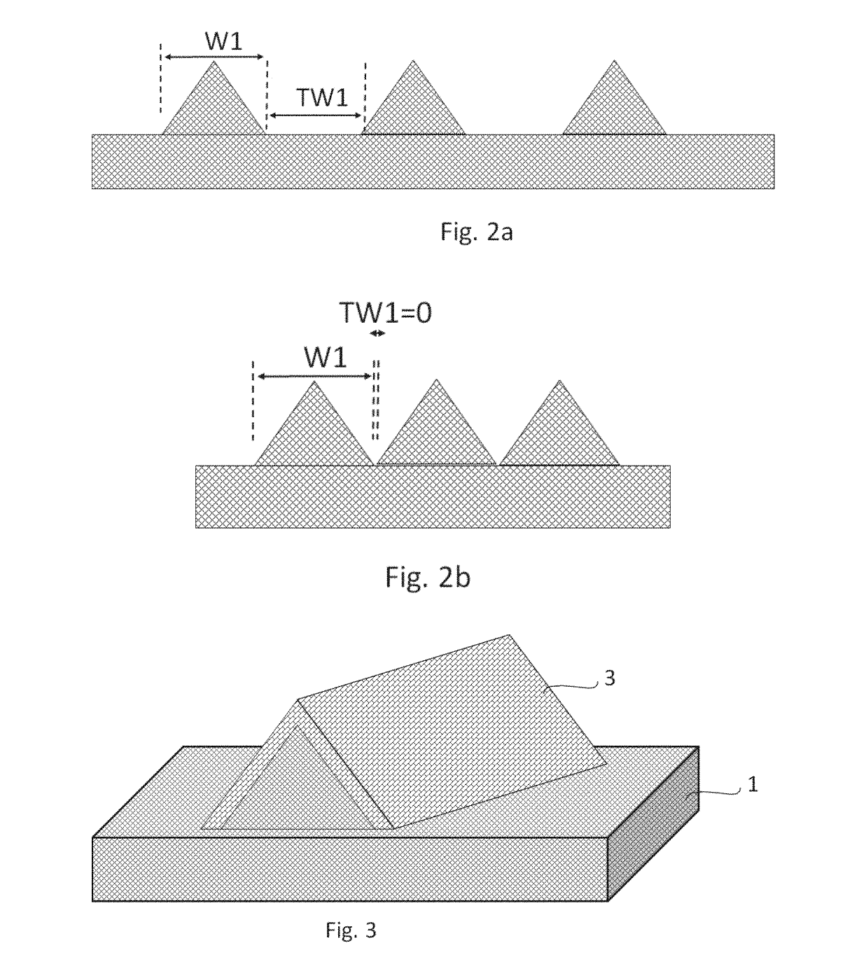

FIGS. 2, 13, and 24 present schematic of V-groove PS, trapezoidal-groove PS, and rectangular cuboid PS, respectively. FIGS. 2a, 13a, and 24a show the cross sectional view of the V-groove PS, trapezoidal-groove PS, and rectangular cuboid PS, respectively.

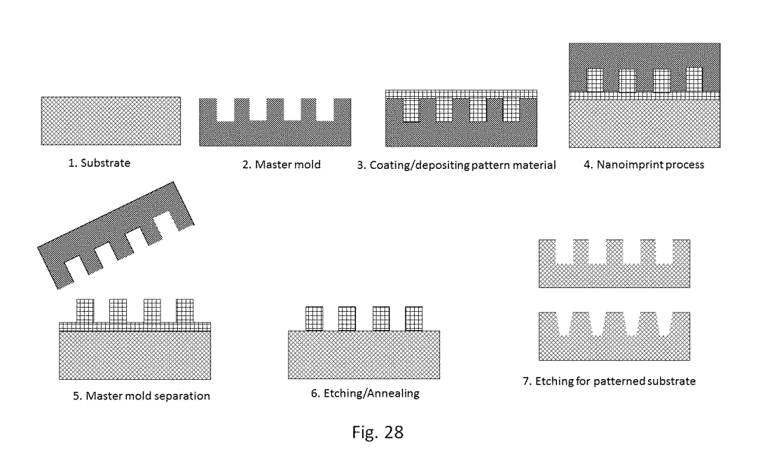

The PSs can be fabricated by either combination of e-beam lithography and wet-chemical etching or combination of e-beam lithography and dry etching or through Nanoimprint transfer of master mold patterns to various wafers followed by etching. For example, potassium hydroxide (KOH) can be used to selective etching to fabricate V-groove 2, or trapezoidal-groove PSs on (100) Si wafer with lithographic patterns made either with e-beam lithography or nanoimprint lithography. Reactive ion etching (RIE) also can be used to fabricate these PSs on Si or GaN on Sapphire or GaN wafers with lithographic patterns made either with e-beam lithography or nanoimprint lithography through transfer of the master mold patterns. The fabrication of PS via nanoimprint lithography followed by etching is described in FIG. 28. A wafer which can be Si, sapphire, GaN-on-sapphire, GaN free-standing, SiC, etc, will be used as the starting substrate. A master mold is then defined and used to make PS (which can be V-groove PS, trapezoidal-groove PS, or rectangular cuboid PS). Any nanoimprint resists (both UV and thermal-based) can be deposited/coated on to the master mold/or on to wafer to be used to generate PS. The standard nanoimprinting process will then be performed to transfer the pattern from master mold to the substrate. After removing master mold, additional etching process may be performed to make clear pattern as well as to remove residual coating layer, followed by an annealing step (annealing temperature varies depending on nanoimprint resists used). The final step of etching then be performed to make PS. Etching can be either wet-chemical etching, dry etching or a combination of both methods. The shape of patterns on substrate depends on the master mold used to create the pattern. With proper master mold, V-groove PS, trapezoidal-groove PS, and rectangular cuboid PS shall be fabricated.

The discussion and description below should be taken to be exemplary in general which is not limited the overall scope of the current version of this invention. PSs enables any laser structures with any materials combinations. We will take III-Nitride LDs as the example to demonstrate the use of three type PSs.

In this invention example, LDs are grown by MBE, MOCVD, CVD or any other epitaxial growth method. The PSs can be fabricated from regular substrate 1, for instance, Si, sapphire, GaN-on-sapphire, GaN wafers, or other suitable wafers.

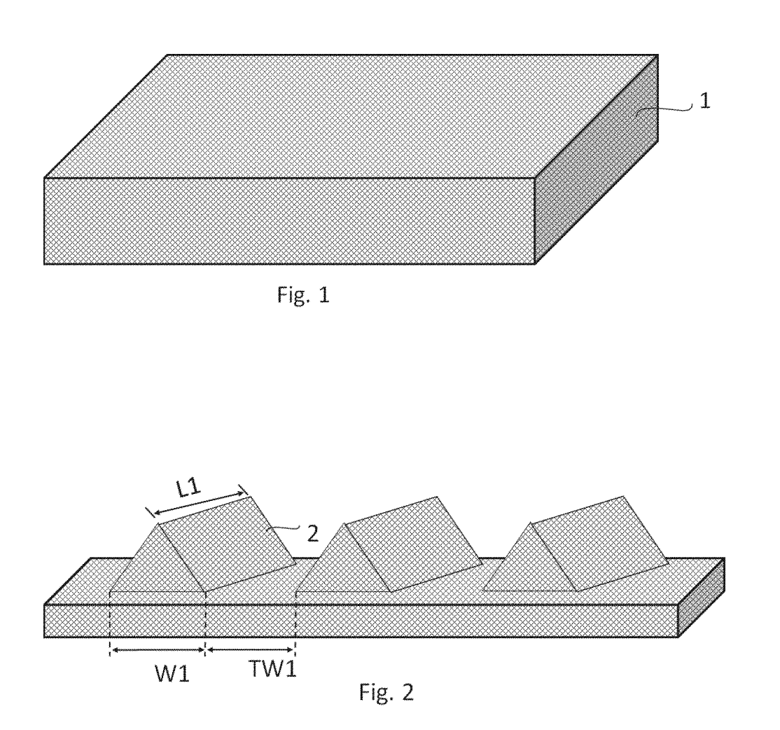

FIG. 1 shows an image of a substrate. The substrate will then be processed to make desired pattern on it with three aforementioned PSs. As described in [006], these PSs can be fabricated by wet-chemical etching, or dry etching, or combination of wet and dry etching processes. Prior to etching process, the pattern can be defined on the proper wafer by either photolithography or more advanced methods, such as electron beam lithography and/or nanoimprint lithography followed by etching.

Before the growth process of LDs, the PSs are cleaned via standard wafer cleaning processes using standard solvent and/or acid solution. The PS is then loaded into growth chamber. Further cleaning step (steps) is (are) used to remove native oxide which was formed on the surfaces of the PSs.

Next step is the epitaxial growth of LD structures on PSs, performed inside growth chamber.

The LD structures can be with single quantum well (for example, AlₓGa₁₋ₓN/Al_{y}Ga_{1-y}N or InᵢGa₁₋ᵢN/AlⱼGa₁₋ⱼN), multiple quantum well, or quantum dots (single layer or multiple layers), served as the active region. The device structure may have n-AlⱼGa₁₋ⱼN (or n-InₖGa₁₋ₖN) bottom cladding layer 3, n-AlₗGa₁₋ₗN (or n-InₘGa₁₋ₘN, or n-GaN) bottom waveguide layer 4, active region with single or multiple quantum wells, or quantum dots (single layer or multiple layers of InᵢGa₁₋ᵢN, AlₓGa₁₋ₓN, AlₙInₚGa₍₁₋ₙ₋ₚ₎N, GaN, or AlN) 5, top waveguide layer (p-AlₗGa₁₋ₗN, p-GaN or p-InₘGa₁₋ₘN) 6, and top cladding layer (P-AlⱼGa₁₋ⱼN or p-InₖGa₁₋ₖN) 7, and final layer of p-contact layer which may be p++-GaN 8 to form ohmic contact on the laser device. For x is in the range of [0-1], y is in the range of [0-1], i is in the range of [0-1], j is in the range of [0-1], k is in the range of [0-1], l is in the range of [0-1], m is in the range of [0-1], n is in the range of [0-1], and p is in the range of [0-1]. Thickness of each layer can be designed and depends on emission wavelength of the LDs operating between UV and IR spectral range.

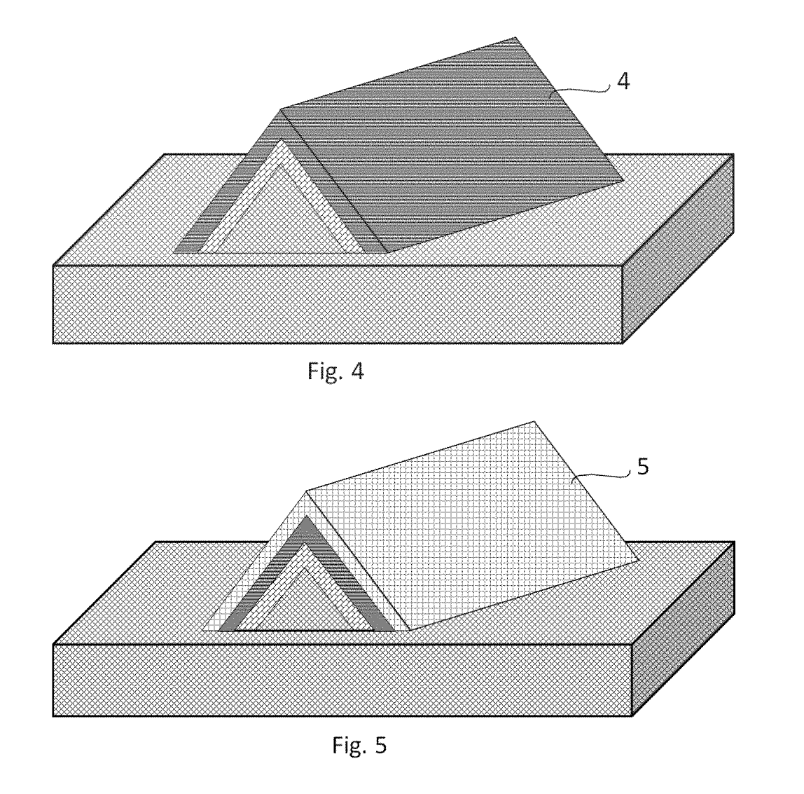

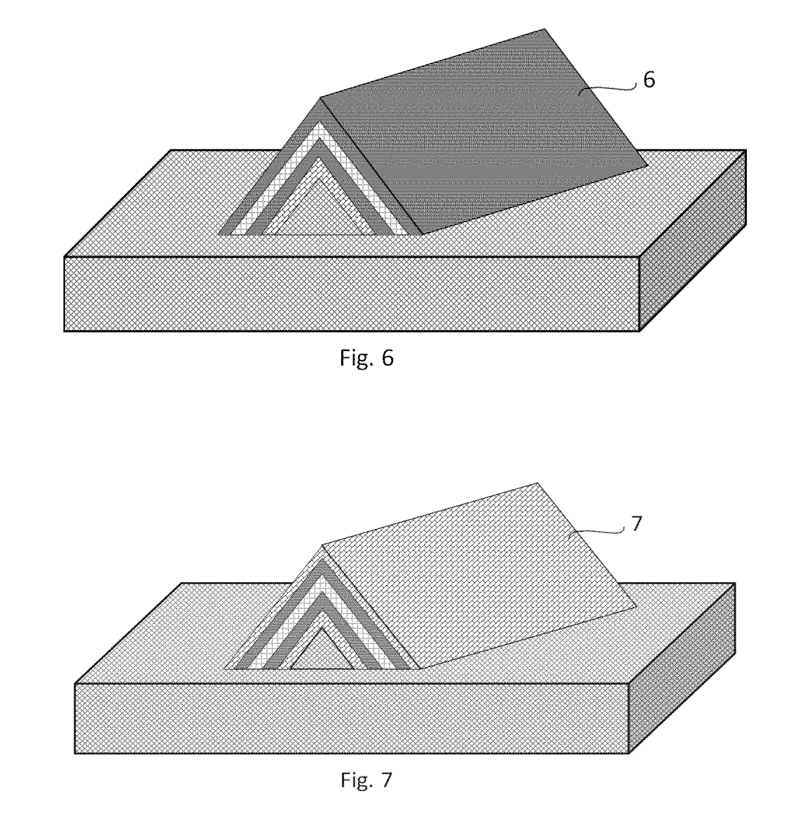

As was stated in [007], three types of PSs will be used in this invention. The first demonstration/disclosure is the fabrication of LDs on V-groove PSs. Illustrated in FIGS. 3, 4, 5, 6, 7, and 8, bottom cladding layer of the LD 3 is first grown on V-groove PS (FIG. 3), following by the growth of bottom waveguide layer 4 (FIG. 4), active region layer 5 (FIG. 5), top waveguide layer 6 (FIG. 6), top cladding layer 7 (FIG. 7), and contact layer 8 (FIG. 8). The growth temperature and growth condition can be adjust accordingly during the growth of each layer. For example, AlGaN are usually grown at higher temperature than GaN and InGaN layers. Also notice that, shown in the all figures in this invention, the thickness of substrates and epi-layers are not proportional. Figures are used to show the LD structures more clearly.

The LD sample will be taken out of the chamber for characterization and device fabrication.

The grown LD sample will be used to fabricate LD devices through standard LD fabrication procedures. Device fabrication process of LD on PSs includes the following steps. The LD sample is first cleaned with solvent and DI water. Dry the sample by nitrogen gas. The LD dimension can be defined by standard photolithography on substrate. Photoresist is then spin-coated for the subsequent photolithography step. The LD stripe, length and top contact is defined on the surface of the LD sample by photolithography. Top metal contact is then deposited at desired position defined previously by photolithography. The back metal contact is then deposited on the backside of the n-type doing Si substrate or GaN free standing substrate. Metal contacts can be Ti/Al, Ti/Au or Al for n-type contact and Ni/Au, Ni/Al, or Ni/Al/Au for p-type contacts. For GaN-on-sapphire substrate, the n-metal contact will be deposited on n-GaN layer after a certain photolithograph step which is necessary to open a window on n-GaN layer for metal deposition. The fabricated devices with metal contacts are annealed at between 400-600° C. (or higher) for 1 to 3 minutes in nitrogen ambient to form good ohmic contacts. The length of laser device will be defined with two end-facets by cleaving the wafer at desired positions. Cleaving wafer can be performed by hard-sharp objective such as diamond pen, or scriber.

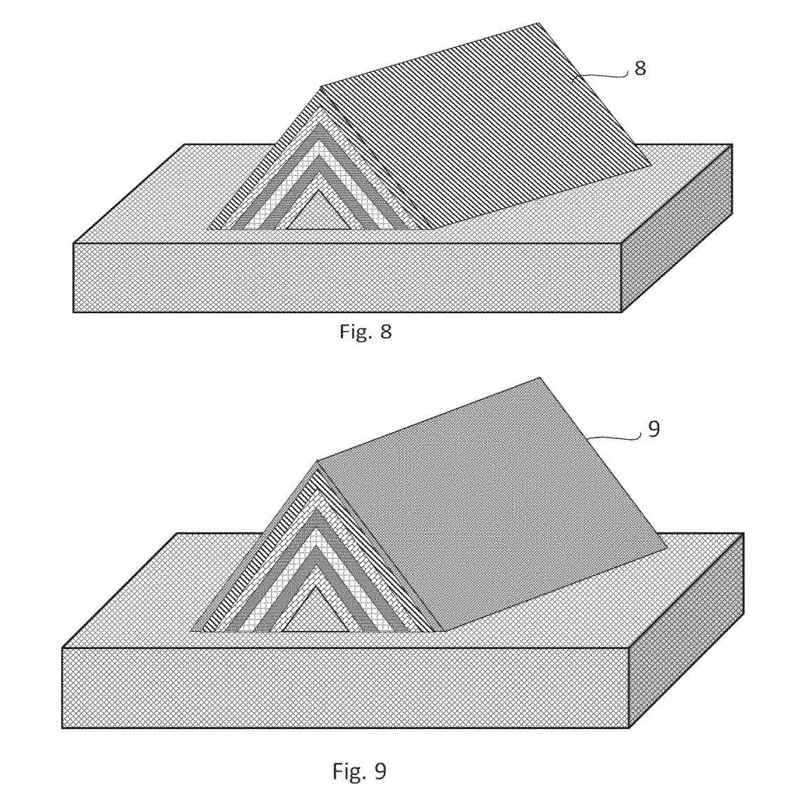

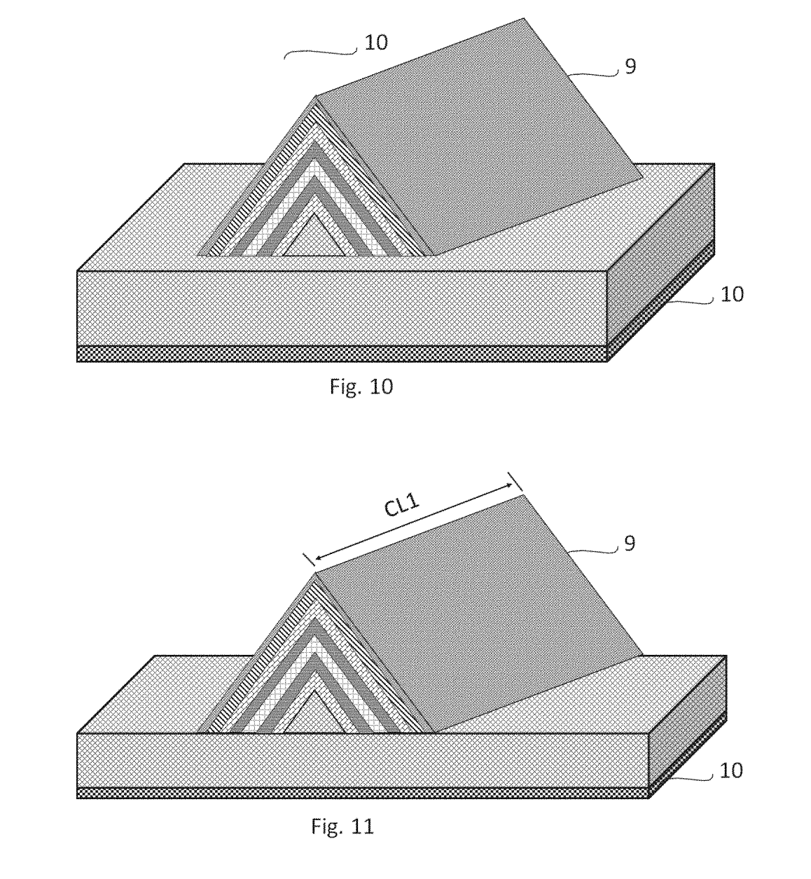

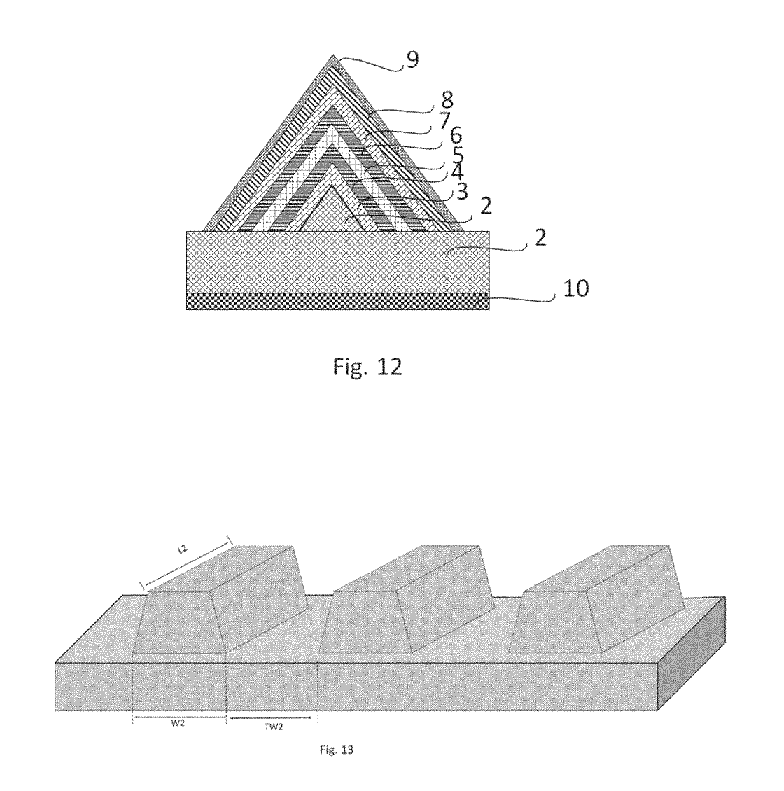

FIG. 9 shows the LD sample after depositing top metal contact 9. FIG. 10 presents the single LD device after being deposited with back metal contact 10. FIG. 11 shows the LD chip with single LD device after cleaving two facets of LD. Additional processing steps may be used to help cleave device easily. FIG. 12 shows the cross sectional view of a LD chip with single LD device showing each layer of the LD including n and p-metal.

The aspect ratio including L1, CL1, and W1, illustrated in FIG. 2 and FIG. 11, can be varied. L1 is the pattern length which is varied from 10 nm to 5 cm or longer, CL1 is the cavity length of the LDs which is varied from 10 nm to 5 mm, or longer. W1 is the width of LDs which can be varied from 10 nm to 5 cm, or longer. The trench width TW1 can be in the range of 0 nm to 3 mm, or longer. A device chip can contain single LD device or multiple LD devices depend on lithography masks used for different applications. FIG. 2b shows the V-groove PS with TW1 is 0.

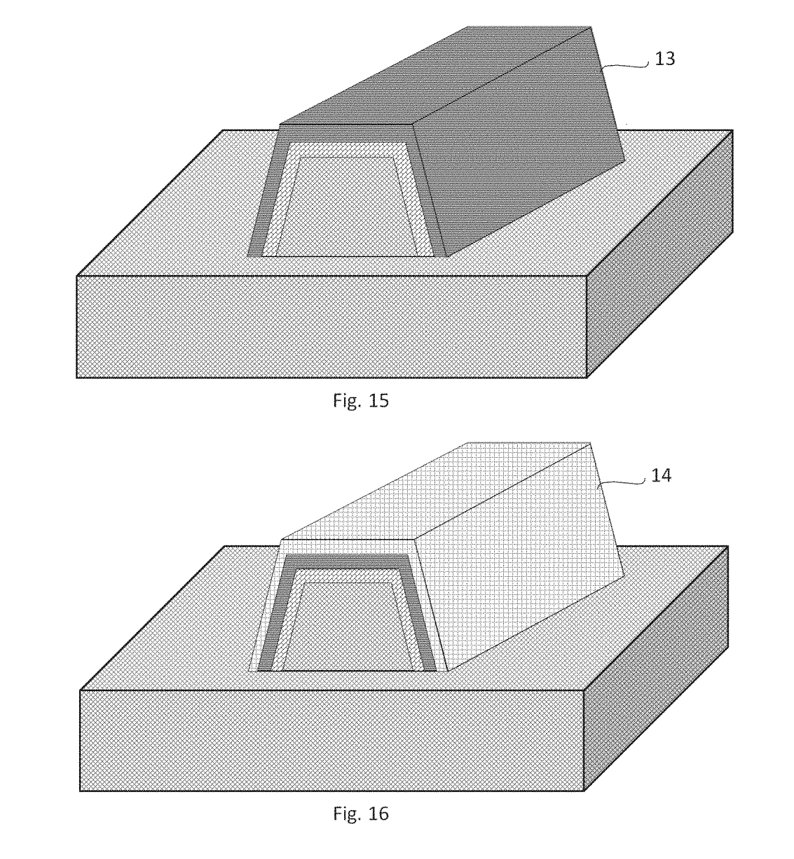

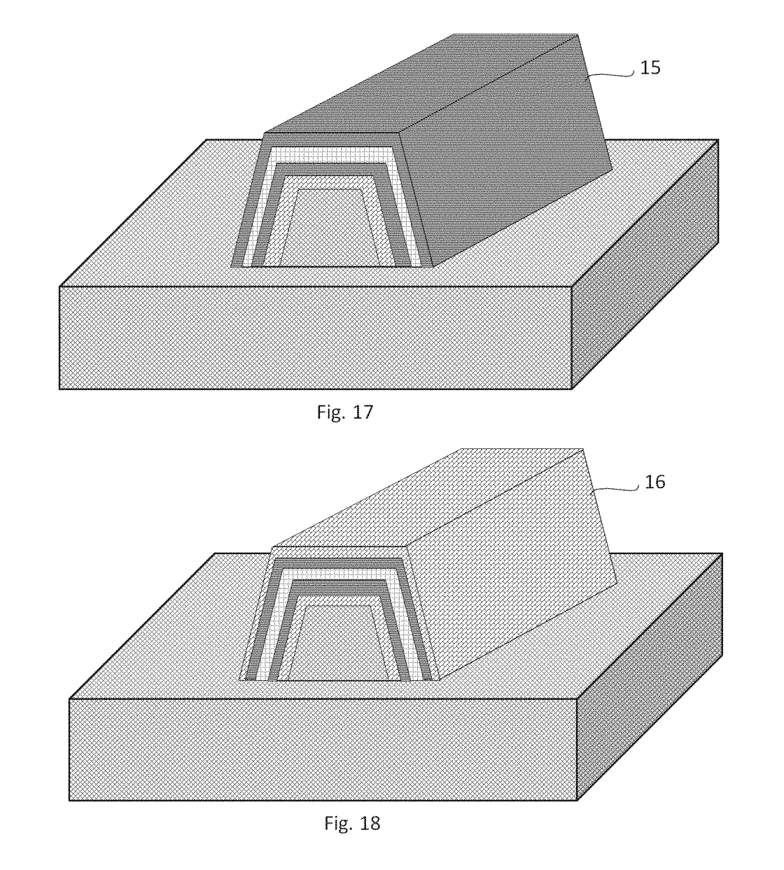

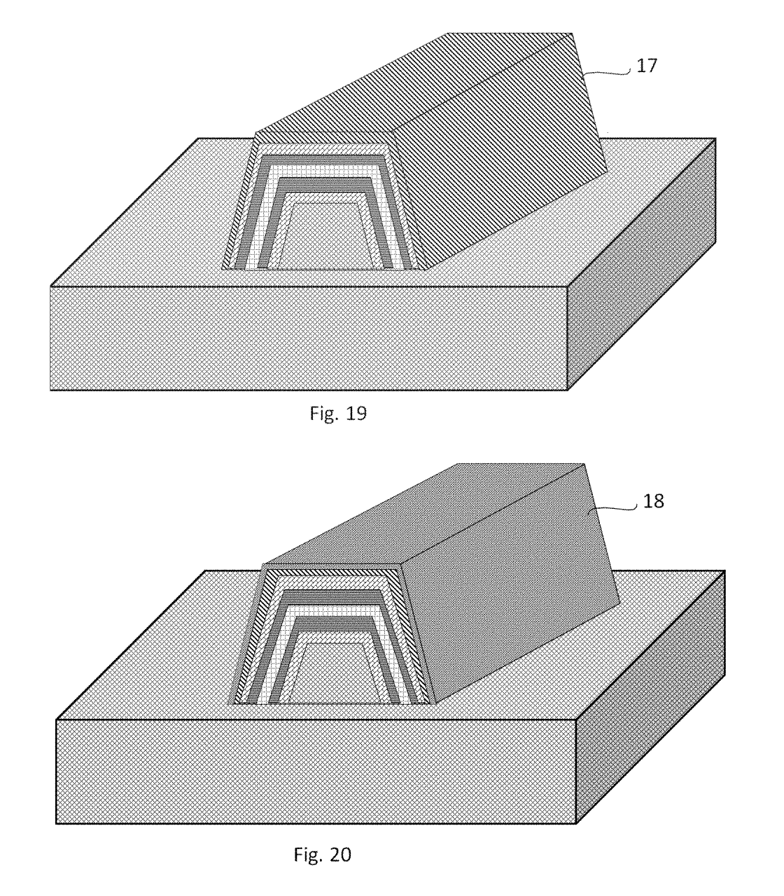

The second demonstration/disclosure is the fabrication of LDs on trapezoidal-groove PS 11. The epitaxial growth of LD on this type of substrate is similar to that of LDs on V-groove PS. The trapezoidal-groove PS is cleaned by standard cleaning procedure before loading into the growth chamber. The LD active region can have single quantum well or multiple quantum well, or quantum dots (single layer or multiple layers), served as the active region 14. The device structure may have n-type bottom cladding layer (can be n-AlⱼGa₁₋ⱼN or n-InₖGa₁₋ₖN) 12, n-type bottom waveguide layer (can be n-AlₗGa₁₋ₗN or n-InₘGa₁₋ₘN, or n-GaN) 13, active region with single or multiple quantum wells (for example, AlₓGa₁₋ₓN/Al_{y}Ga_{1-y}N or InᵢGa₁₋ᵢN/GaN), or quantum dots (single layer or multiple layers of InᵢGa₁₋ᵢN, AlₓGa₁₋ₓN, AlₙInₚGa₍₁₋ₙ₋ₚ₎N, GaN, or AlN) 14, p-type top waveguide layer (can be p-AlₗGa₁₋ₗN, p-GaN or p-InₘGa₁₋ₘN) 15, p-type top cladding layer (can be AlⱼGa₁₋ⱼN or p-InₖGa₁₋ₖN) 16, and heavily doped contact layer which may be p⁺⁺-GaN 17. Presented in FIGS. 14, 15, 16, 17, 18 and 19, the epitaxial growth of LD structure can be performed as follow: bottom cladding layer of the LD 12 is first grown on trapezoidal-groove PS (FIG. 14), followed by the epitaxial growth of bottom waveguide layer 13 (FIG. 15), active region layer 14 (FIG. 16), top waveguide layer 15 (FIG. 17), top cladding layer 16 (FIG. 18), heavily doped contact layer 17 (FIG. 19).

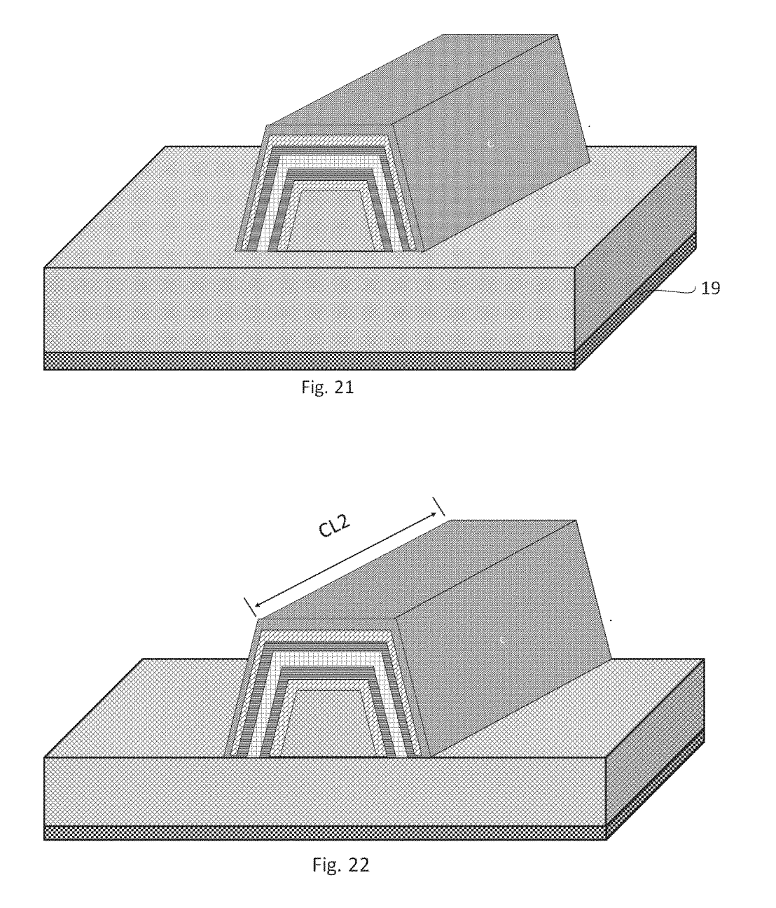

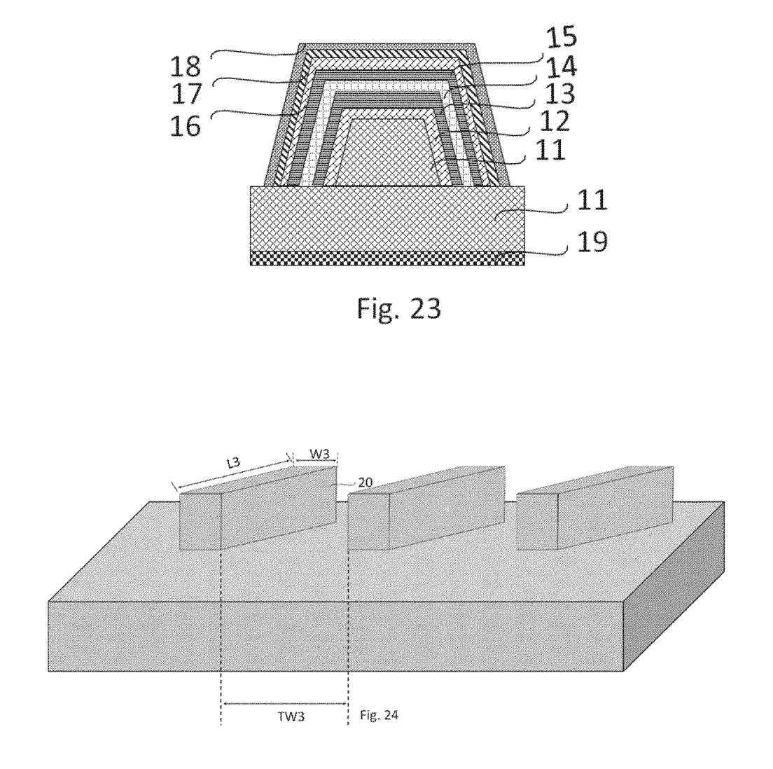

The LD on trapezoidal-groove PS sample will be taken out of the chamber and process device fabrication. The fabrication procedure of LDs is similar to the one shown in the first demonstration/disclosures (presented in the device fabrication section [015]). FIG. 20 shows the LD sample after depositing top metal contact 18. FIG. 21 presents the LD sample after being deposited with back metal contact 19. FIG. 22 shows a LD chip with single LD device after forming two mirrored facets with cleaving. Additional processing steps may be used to help cleave device easily. FIG. 23 shows the cross sectional view of a LD chip with single LD device on trapezoidal-groove PS presenting clearly each layer of the LD. A device chip can contain single LD device or multiple LD devices depend on lithography masks used for different applications.

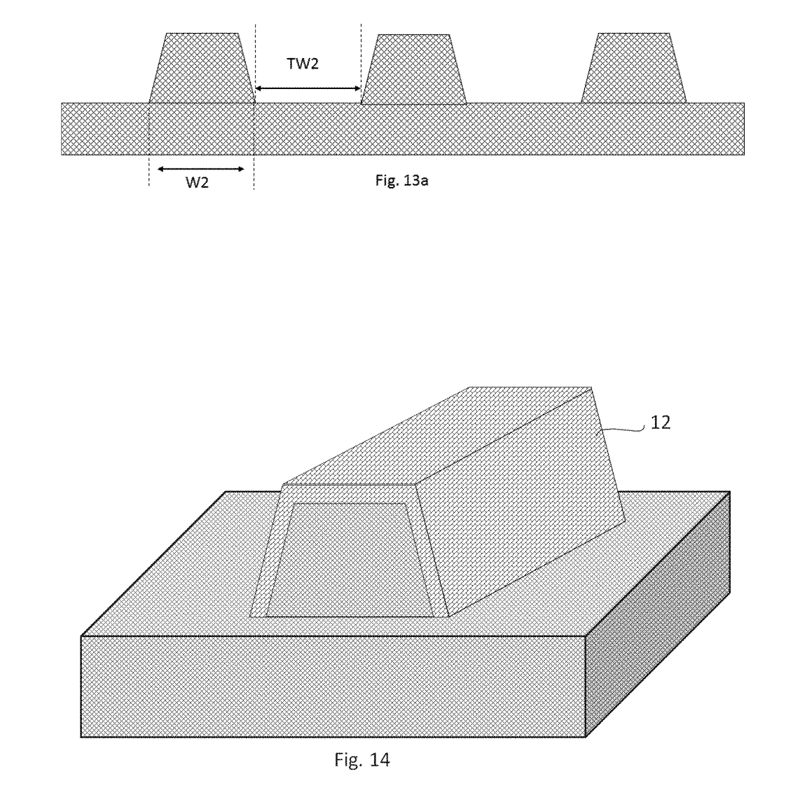

The aspect ratio including L2, CL2, and W2, illustrated in FIG. 13 and FIG. 22, can be varied. L2 is the pattern length which is varied from 10 nm to 5 cm or longer, CL2 is the cavity length of the LDs which is varied from 10 nm to 5 mm, or longer. W2 is the width of LDs which can be varied from 10 nm to 5 cm, or longer. The trench width TW2 can be in the range of 110 nm to 5 mm, or longer.

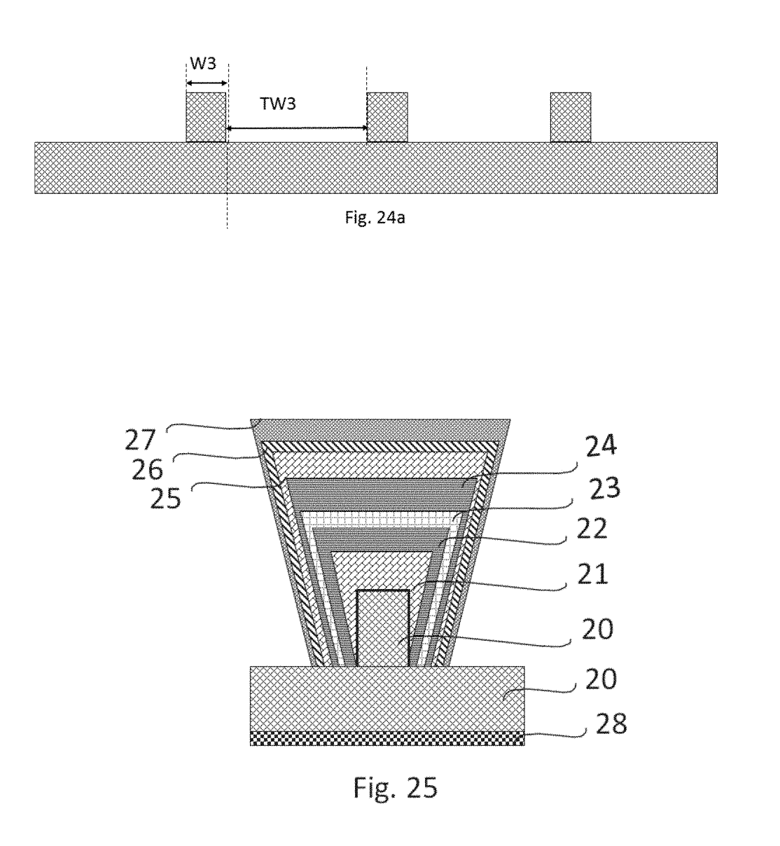

The third demonstration/disclosure is the fabrication of LDs on rectangular/square cuboid-groove PS 20. The epitaxial growth of LDs on this type of substrate is similar to that of LDs on V-groove PS. Since the procedure for growing and fabricating rectangular cuboid-groove PS and square cuboid-groove PS is similar, in this description, only the rectangular cuboid-groove PS 20 is presented, shown in FIG. 24. The rectangular cuboid-groove PS is first cleaned by standard cleaning procedure before loading into the growth chamber. The LD active region can have single quantum well or multiple quantum well, or quantum dots (single layer or multiple layers), served as the active region 23. The device structure may have n-type bottom cladding layer (can be n-AlⱼGa₁₋ⱼN or n-InₖGa₁₋ₖN) 21, n-type bottom waveguide layer (can be n-AlᵢGa₁₋ₗN or n-InₘGa₁₋ₘN, or n-GaN) 22, active region with single or multiple quantum wells 23 (can be AlₓGa₁₋ₓN/Al_{y}Ga_{1-y}N or InᵢGa₁₋ᵢN/GaN), or quantum dots (single layer or multiple layers of InᵢGa₁₋ᵢN, AlₓGa₁₋ₓN, AlₙInₚGa₍₁₋ₙ₋ₚ₎N, GaN, or AlN), p-type top waveguide layer (p-AlₗGa₁₋ₗN, p-GaN or p-InₘGa₁₋ₘN) 24, p-type top cladding layer (can be AlⱼGa₁₋ⱼN or p-InₖGa₁₋ₖN) 25, and heavily doped contact layer 26 which can be p-GaN. Presented in FIGS. 25, is a cross section view of the LD on the rectangular cuboid-groove PS. The epitaxial growth of LD structure can be performed as follow: bottom cladding layer of the LD 21 is first grown on rectangular cuboid-groove PS, followed by the epitaxial growth of bottom waveguide layer 22, active region layer 23, top waveguide layer 24, top cladding layer 25, and heavily doped contact layer 26.

The aspect ratio including L3, CL3, and W3, illustrated in FIG. 24 and FIG. 27, can be varied. L3 is the pattern length which is varied from 10 nm to 5 cm or longer, CL3 is the cavity length of the LDs which is varied from 10 nm to 5 mm, or longer. W3 is the width of LDs which can be varied from 10 nm to 5 cm, or longer. The trench width TW3 can be in the range of 10 nm to 5 mm, or longer

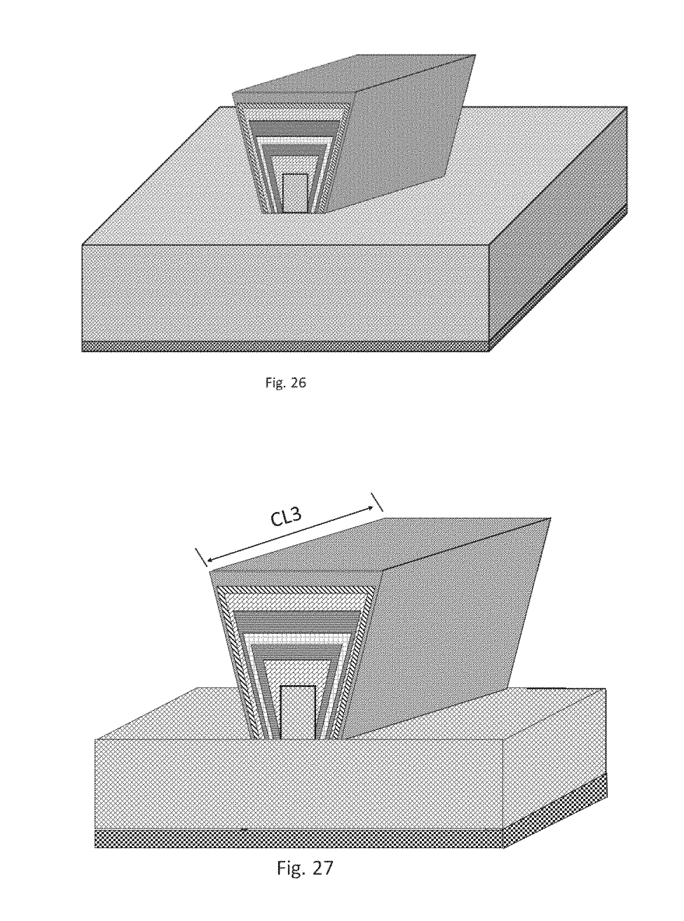

Similarly, the LD sample will be taken out of the chamber and going through device fabrication process similar to the one shown in the first or second demonstration/disclosures. FIG. 26 shows the LD sample after deposition top metal contact 27 and back metal contact 28. FIG. 27 shows the laser chip with single LD device after forming two mirror facets with cleaving. Additional processing steps may be used to help cleave device easily. A device chip can contain single LD device or multiple LD devices depend on lithography masks used for different applications.

It will be apparent to those skilled in the art of UV LDs, LEDs, and silicon integrated sensor that many modifications and substitutions can be made to the preferred embodiments described herein without departing from the spirit and scope of the present invention which is specifically set forth in the appended claims.

1. A method comprising:
fabricating a patterned substrate, the patterned substrate including at least one of a V-groove patterned substrate, a trapezoidal-groove patterned substrate, or a rectangular/square cuboid patterned substrate;
fabricating a laser diode or a light emitting diode on the patterned substrate; and
reducing dislocation and enhancing crystalline quality of epitaxial growth of semiconductor with the patterned substrate.

2. The method of claim 1, further comprising:
using the patterned substrate for high performance optoelectronic devices, wherein the patterned substrate includes at least one of: Si, GaN-on-sapphire, sapphire, GaN free-standing, III-V, II-VI, or Ge,
wherein fabricating the patterned substrate includes fabricating by at least one of a combination of e-beam lithography and wet-chemical etching, a combination of e-beam lithography and dry etching, a combination of e-beam lithography and wet-chemical etching and dry etching, or nanoimprint lithography followed by etching.

3. The method of claim 1,
wherein the laser diode on the patterned substrate is configured to operate in deep ultraviolet to visible and to infrared regions,
wherein fabricating the laser diode includes growing the laser diode on the patterned substrate by at least one of MBE, MOCVD, or an epitaxial technique.

4. A device comprising epitaxial growth laser diode structures on a patterned substrate for reduced dislocation densities.

5. A device according to claim 4, wherein the laser diode structures include:
laser diode on patterned substrate with V-groove shape;
laser diode on patterned substrate with trapezoidal-groove shape;
laser diode on patterned substrate with rectangular/square cuboid shape; and
a laser diode on a patterned substrate with a combination of V-groove, trapezoidal-groove, and rectangular/square cuboid shapes.

6. A device according to claim 4, wherein the laser diode structures include:
a laser diode device with at least one of: single quantum well, multiple quantum well or quantum dot in the active region; and
a laser diode device that operates in a range of emission, wavelengths from deep ultraviolet to infrared regions.

7. The method of claim 1, further comprising growing a semiconductor structure including at least one of a p-i-n or p-n diode, a light emitting diode, a superluminescent light emitting diode, a photodiode, a laser diode, a sensor, or a solar cell, by at least one of MBE, MOCVD, or an epitaxial technique.

8. The method of claim 1, further comprising:
growing a Light Emitting Device in the UV, visible, and infrared regions on the patterned substrate,
wherein the patterned substrate is made from at least one of: Si, GaN-on-sapphire, sapphire, or GaN free-standing.

9. The method of claim 1, further comprising:
growing a sensor device on the patterned substrate,
wherein the sensor device includes Si_{1-x-y} Geₓ Sn_{y}, wherein 0≤x≤1, and 0≤y≤1, and
wherein the patterned substrate is made with at least one of: Silicon, SiOₓ-on-Silicon, III-V, II-VI, or Ge.

10. A device comprising:
a structure including at least one of a V-groove patterned substrate, a trapezoidal-groove patterned substrate, and a rectangular/square cuboid patterned substrate,
wherein the at least one patterned substrate is made from at least one of: Si, GaN-on-sapphire, sapphire, GaN free-standing, SiOₓ-on-Silicon, III-V, II-VI, or Ge.

11. The device of claim 10, wherein the structure is a laser diode.

12. The device of claim 10, wherein the structure is a light emitting diode.

13. The device of claim 10, wherein:
the structure is a sensor device; and
the at least one patterned substrate is made from at least one of: Si, SiOₓ-on-Silicon, or III-V, II-VI, or Ge.

14. The device of claim 13, wherein an active region contains Si_{1-x-y} Geₓ Sn_{y}, wherein 0≤x≤1, and 0≤y≤1.

15. The device of claim 13, wherein an active region contains at least one of: AlₓGa₁₋ₓN, InₓGa₁₋ₓN, InAsₓSb₁₋ₓ, HgₓCd₁₋ₓTe, InSb, or InAs, wherein 0≤x≤1, and 0≤y≤1.

16. A device comprising epitaxial growth light emitting diode structures on patterned substrates for reduced dislocation densities.

17. A device according to claim 16, wherein the light emitting diode structures on patterned substrates include:
a light emitting diode on a patterned substrate with a V-groove shape;
a light emitting diode on a patterned substrate with a trapezoidal-groove shape;
a light emitting diode on a patterned substrate with a rectangular/square cuboid shape; and
a light emitting diode on a patterned substrate with a combination of V-groove, trapezoidal-groove, and rectangular/square cuboid shapes.
